(19) United States
(12) Patent Application Publication
(10) Pub. No.: US 2012/0139560 A1
(43) Pub. Date: Jun. 7, 2012

(54) TOUCH APPARATUS

(76) Inventors: Sean CHANG, Taoyuan Hsien (TW); Chii-How CHANG, Taoyuan Hsien (TW); Chin-Wei KUO, Taoyuan Hsien (TW)

(21) Appl. No.: 13/010,578

(22) Filed: Jan. 20, 2011

(30) Foreign Application Priority Data
Dec. 1, 2010 (TW) 099141662

(51) Int. Cl. G01R 27/26

(52) U.S. Cl. 324/659

(57) ABSTRACT

A touch apparatus includes a touch unit, a detecting unit, and a compensation unit. The touch unit has a touch substrate and at least one conductive layer. The conductive layer is disposed on the touch substrate. The detecting unit is electrically connected with the conductive layer of the touch unit and outputs a driving signal to the conductive layer. A first parasitic capacitance is formed between the detecting unit and a ground. The compensation unit is electrically connected with the detecting unit and the touch unit and outputs a compensation signal to the first parasitic capacitance. Hence, the touch apparatus can eliminate the parasitic capacitance effect.

### CROSS REFERENCE TO RELATED APPLICATIONS

This Non-provisional application claims priority under 35 U.S.C. §119(a) on Patent Application No(s). 099141662 filed in Republic of China on Dec. 1, 2010, the entire contents of which are hereby incorporated by reference.

### BACKGROUND OF THE INVENTION

1. Field of Invention

The invention relates to a touch apparatus.

2. Related Art

With more and more queries for the multi-media information, the touch screen has been gradually used by users and takes the place of the mouse and keyboard as the input means. This is because that the touch screen is easy to operate and user-friendly, and it can reduce the spaces for configuration. The touch screen has been widely applied to various fields, such as the tourist guide system, automated teller machine (ATM), portable phone, notebook, POS (point of service) terminal and industrial control system.

As shown in FIG. 1, a conventional touch apparatus 1 is used in cooperation with a display apparatus A, and the display apparatus A is disposed under the touch apparatus 1. The touch apparatus 1 includes a touch unit 11 and a detecting unit 12. The touch unit 11 includes a touch substrate, at least one conductive layer, at least one insulating layer and an electrical shielding layer (not shown). The conductive layer is disposed between the touch substrate and the insulating layer. The electrical shielding layer is disposed under the insulating layer and the conductive layer to protect the touch apparatus 1 from being affected by the signals of the display apparatus A. There exists a parasitic capacitance between the detecting unit 12 and a ground G.

Before the touch apparatus 1 is touched by a finger, there exists a parasitic capacitance C7 between the detecting unit and the ground G, and there also exists a parasitic capacitance between the conductive layer and the electrical shielding layer (not shown). When the finger touches the touch apparatus 1, a capacitance (not shown) is formed at the touch substrate. In this case, the detecting unit 12 of the touch apparatus 1 transmits a driving signal to the conductive layers to detect the capacitance to obtain the touch position and touch status. However, the capacitance formed by touching the touch apparatus 1 is just dozens of picofarads (pF), but the parasitic capacitance C7 between the detecting unit 12 and the ground G and the parasitic capacitance between the electrical shielding layer and the conductive layer 12 are approximately from hundreds of picofarads to thousands of picofarads, so that the detection of the capacitance formed by touching the touch apparatus 1 is easily affected by the parasitic capacitance between the detecting unit 12 and the ground G and that between the electrical shielding layer and the conductive layers.

### SUMMARY OF THE INVENTION

In view of the foregoing subject, an object of the invention is to provide a touch apparatus that can eliminate the influence of the parasitic capacitances.

To achieve the above object, a touch apparatus of the invention includes a touch unit, a detecting unit and a compensation unit. The touch unit includes a touch substrate and at least one conductive layer disposed to a side of the touch substrate. The detecting unit is electrically connected with the conductive layer of the touch unit and outputs a driving signal to the conductive layer. A first parasitic capacitance is formed between the detecting unit and a ground. The compensation unit is electrically connected with the detecting unit and the conductive layer of the touch unit and outputs a compensation signal to the first parasitic capacitance.

In one embodiment of the invention, the touch unit further includes an insulating layer which has a first side and a second side opposite to the first side. The conductive layer is disposed between the first side of the insulating layer and the touch substrate.

In one embodiment of the invention, the touch unit further has a second parasitic capacitance which is formed between the conductive layer and the second side of the insulating layer.

In one embodiment of the invention, the compensation signal output by the compensation unit outputs is also transmitted to the second parasitic capacitance.

In one embodiment of the invention, the touch unit further includes an electrical shielding layer, and the insulating layer is disposed between the conductive layer and the electrical shielding layer.

In one embodiment of the invention, the detecting unit includes a voltage-drop device, a retrieving device and an operation device. One end of the voltage-drop device is electrically connected with the touch unit. The input end of the retrieving device is electrically with two ends of the voltage-drop device. The operation device is electrically connected with the output end of the retrieving device.

In one embodiment of the invention, the compensation unit includes an energy storing device electrically connected with the detecting unit.

To achieve the above object, a touch apparatus of the invention includes a touch unit, a detecting unit and a first compensation unit. The touch unit includes a touch substrate, an electrical shielding layer and at least one conductive layer which is disposed between the touch substrate and the electrical shielding layer. The detecting unit is electrically connected with the conductive layer of the touch unit and outputs a driving signal to the conductive layer. The first compensation unit is electrically connected with the electrical shielding layer. A first parasitic capacitance is formed between the detecting unit and a ground, a second parasitic capacitance is formed between the conductive layer and the electrical shielding layer, and the compensation unit outputs a first compensation signal to the first parasitic capacitance and the second parasitic capacitance.

In one embodiment of the invention, the touch unit further includes at least one insulating layer which is disposed between the conductive layer and the electrical shielding layer.

In one embodiment of the invention, the detecting unit includes a voltage-drop device, a retrieving device and an operation device. One end of the voltage-drop device is electrically connected with the touch unit. The input end of the retrieving device is electrically with two ends of the voltage-drop device. The operation device is electrically connected with the output end of the retrieving device.

In one embodiment of the invention, the first compensation unit includes an energy storing device, which is electrically connected with the electrical shielding layer.

In one embodiment of the invention, the touch apparatus further includes a second compensation unit, which is electrically connected with the detecting unit and outputs a second compensation signal to the first parasitic capacitance and the second parasitic capacitance.

In one embodiment of the invention, the second compensation unit includes an energy storing device electrically connected with the detecting unit.

As mentioned above, the touch apparatus of the invention is configured with a compensation unit for outputting a compensation signal to charge the first and second parasitic capacitances to the full level. Accordingly, when the detecting unit detects the value and position of the capacitance formed by touching the touch apparatus, the detection of the capacitance can not be affected by the first and second parasitic capacitances due to their constant full level. Therefore, the touch apparatus of the invention can eliminate the influence of the parasitic capacitance, so as to enhance the accuracy of the detection of the touch position and touch status.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a diagram of a conventional touch apparatus;

FIG. 2 is a diagram of a touch apparatus of the first embodiment of the invention;

FIG. 3 is a circuit diagram of the touch apparatus of the first embodiment of the invention;

FIG. 4 is a diagram of signal waveforms of the touch apparatus of the first embodiment of the invention;

FIG. 5 is a diagram of a touch apparatus of the second embodiment of the invention;

FIG. 6 is a diagram of a touch apparatus of the third embodiment of the invention;

FIG. 7 is a diagram of a touch apparatus of the fourth embodiment of the invention;

FIG. 8 is a diagram of a touch apparatus of the fifth embodiment of the invention;

FIG. 9 is a circuit diagram of the touch apparatus of the fifth embodiment of the invention;

FIG. 10 is a diagram of a touch apparatus of the sixth embodiment of the invention; and

FIG. 11 is a circuit diagram of the touch apparatus of the sixth embodiment of the invention.

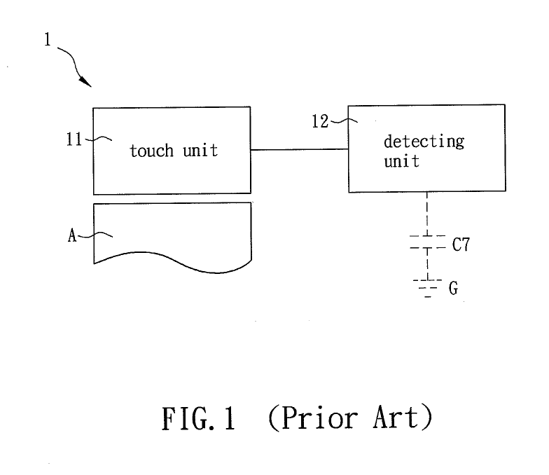

### DETAILED DESCRIPTION OF THE INVENTION

The present invention will be apparent from the following detailed description, which proceeds with reference to the accompanying drawings, wherein the same references relate to the same elements.

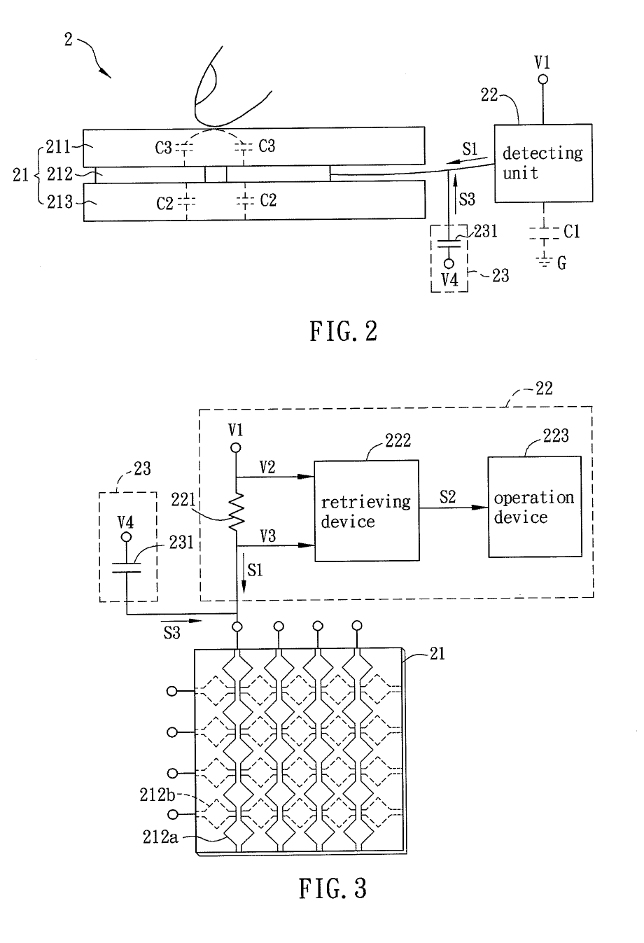

FIG. 2 is a diagram of a touch apparatus according to a first embodiment of the invention, and FIG. 3 is a circuit diagram of the touch apparatus according to the first embodiment of the invention. The touch apparatus 2 includes a touch unit 21, a detecting unit 22 and a compensation unit 23.

The touch unit 21 includes a touch substrate 211, at least one conductive layer 212 and at least one insulating layer 213. The conductive layer 212 is disposed to a side of the touch substrate 211. The conductive layer 212 includes a row conductive layer 212a (indicated by the continuous line in FIG. 3) and a column conductive layer 212b (indicated by the dotted line in FIG. 3), and the row conductive layer 212a and the column conductive layer 212b are not on the same plane. The conductive layer 212 can be a transparent thin-film conductive layer. The insulating layer 213 has a first side and a second side opposite to the first side. The conductive layer 212 is disposed between the first side of the insulating layer 213 and the touch substrate 211. Besides, another insulating layer (not shown) is disposed between the row conductive layer 212a and the column conductive layer 212b.

The detecting unit 22 is electrically connected with the conductive layer 212 of the touch unit 21 and outputs a driving signal S1 to the conductive layer 212. There exists a first parasitic capacitance C1 between the detecting unit 22 and a ground G. Besides, the touch unit 21 further include a second parasitic capacitance C2 formed between the conductive layer 212 and the second side of the insulating layer 213. The detecting unit 22 includes a voltage-drop device 221, a retrieving device 222 and an operation device 223. One end of the voltage-drop device 221 is electrically connected with the touch unit 21, and the other end of the voltage-drop device 221 receives a power signal V1. The input end of the retrieving device 222 is electrically connected with two ends of the voltage-drop device 221. The retrieving device receives two voltage signals V2 and V3 according to the voltages of the two ends of the voltage-drop device 221 and compares the voltage signals V2 and V3 to output a voltage difference signal S2. The operation device 223 is electrically connected with the output end of the retrieving device 222, receives the voltage difference signal S2, and obtains the touch position and touch status according to the variation of the voltage difference signal S2. The structure of the detecting unit 22 is just for illustration but not for limiting the invention.

The compensation unit 23 is electrically connected with the touch unit 21 and the detecting unit 22, and receives a power signal V4 of alternating current (AC) and outputs a compensation signal S3 to the first parasitic capacitance C1 of the detecting unit 22 and the second parasitic capacitance C2 of the touch unit 21. In the embodiment, the compensation signal S3 transmitted by the compensation unit 23 can charge the first and second parasitic capacitances C1 and C2 to the full level. The compensation unit 23 can include at least one energy storing device 231 according to the practical need. In the embodiment, the compensation unit 23 includes an energy storing device 231, which is a capacitor here. One end of the energy storing device 231 is electrically connected with the conductive layer 212 and the detecting unit 22. The energy storing device 231 is utilized for separating the power signal V4 from the compensation signal S3. Besides, the direct current (DC) level of the power signal V4 is the same as that of the compensation signal S3, so that the compensation unit 23 can provide the compensation effect.

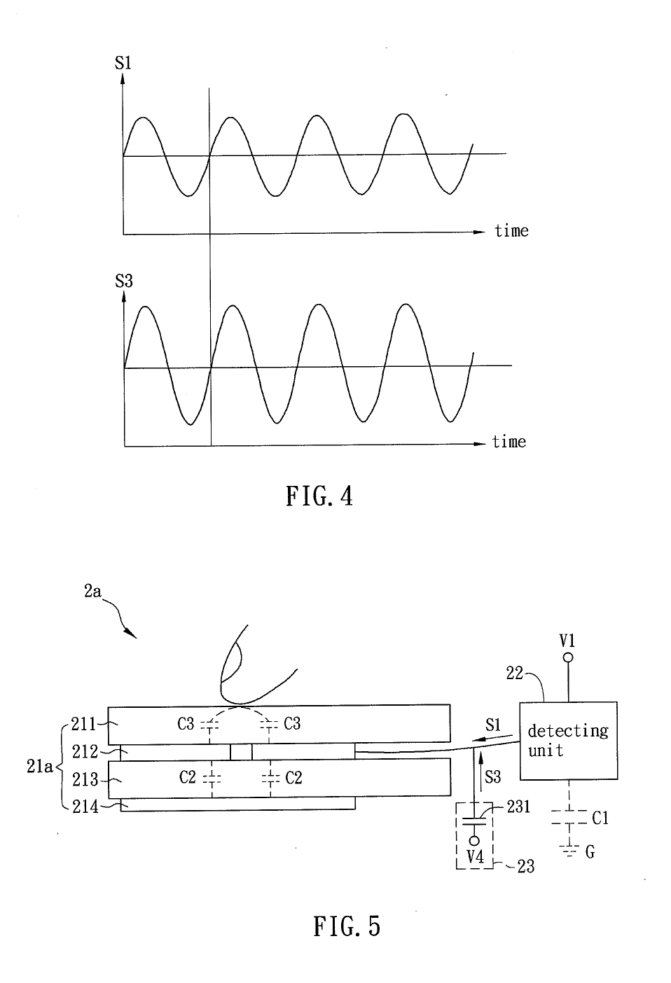

FIG. 4 is a diagram of signal waveforms of the touch apparatus of the first embodiment of the invention. As shown in FIG. 4, the compensation signal S3 can be synchronized with the driving signal S1. The driving signal S1 and the compensation signal S3 have the same frequency and phase, however, the amplitude of the driving signal S1 is larger or less than that of the compensation signal S3. In the embodiment, the amplitude of the compensation signal S3 is larger than that of the driving signal S1, for example. Accordingly, the impact of the first and second parasitic capacitances C1 and C2 on the detection of the touch position can be reduced.

FIG. 5 is a diagram of the touch apparatus 2a of the second embodiment of the invention. Different from the touch apparatus 2 of the first embodiment, the touch apparatus 2a further includes an electrical shielding layer 214 disposed to the second side of the insulating layer 213 so that the insulating layer 213 is disposed between the conductive layer 212 and the electrical shielding layer 214. The material of the electrical shielding layer 214 can include conductive material, such as indium tin oxide (ITO).

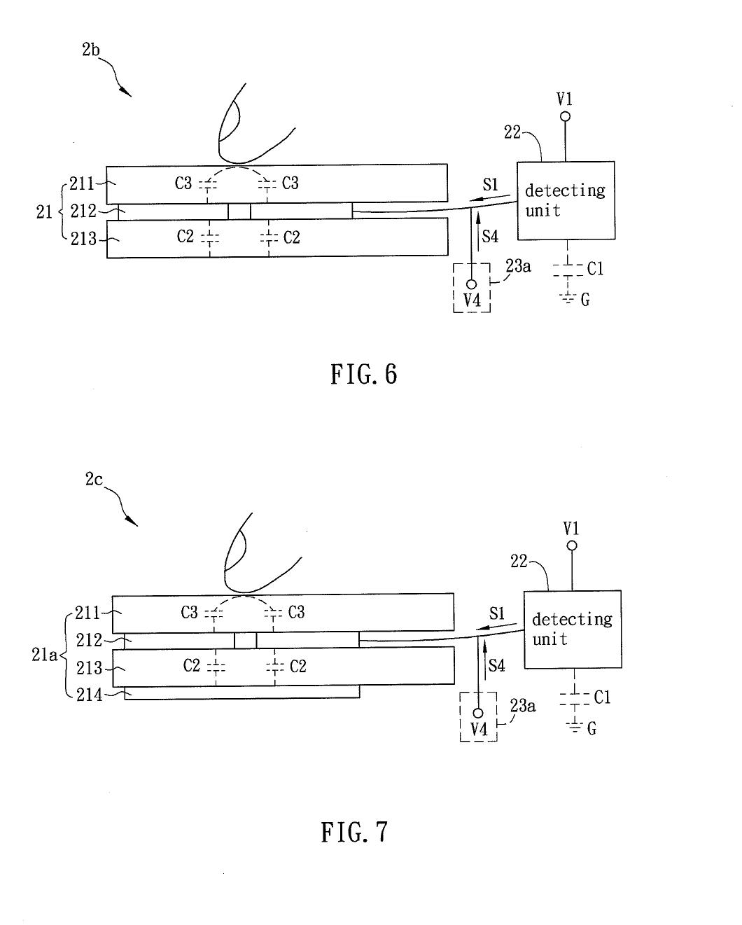

FIG. 6 is a diagram of the touch apparatus 2b of the third embodiment of the invention. Different from the touch apparatus 2 of the above embodiment, the compensation unit 23a of the touch apparatus 2b doesn't include any energy storing device, for example. The compensation unit 23a receives the power signal V4 and thus outputs a compensation signal S4 to compensate the first and second parasitic capacitances C1 and C2. The compensation signal S4 can be synchronized with the driving signal S1, the driving signal S1 and the compensation signal S4 have the same frequency and phase, and the amplitude of the driving signal S1 is less or larger than that of the compensation signal S4.

FIG. 7 is a diagram of the touch apparatus 2c of the fourth embodiment of the invention. Different from the touch apparatus 2 of the above embodiment, the touch unit 21a of the touch apparatus 2c further includes an electrical shielding layer 214 disposed to the second side of the insulating layer 213 so that the insulating is disposed between the conductive layer 212 and the electrical shielding layer 214. Besides, the compensation unit 23a of the touch apparatus 2c doesn't have any energy storing device, for example. The compensation unit 23a receives the power signal V4 and thus outputs a compensation signal S4 to compensate the first and second parasitic capacitances C1 and C2.

Referring to FIG. 2 and FIG. 3 again, when the touch apparatus 2 is touched by a finger, a capacitance C3 is formed at the touch substrate 211. By detecting the capacitance C3, the touch position and whether the touch apparatus 2 is touched can be determined. To easily acquire the touch position and touch status, the compensation unit 23 of the touch apparatus 2 outputs a compensation signal S3 to charge the first and second parasitic capacitances C1 and C2. Besides, according to FIG. 4, the compensation signal S3 is larger than the driving signal S1, so that the influence of the first and second parasitic capacitances C1 and C2 can be eliminated. Therefore, the disturbances caused by the first and second parasitic capacitances C1 and C2 can be eliminated when the detecting unit 22 detects the value and position of the capacitance C3. The detecting unit 22 outputs a driving signal S1 to the conductive layer 212 for detecting the capacitance C3. In this case, the retrieving device 222 of the detecting unit 22 collects and amplifies the voltages of two ends of the voltage-drop device 221 to produce a voltage difference signal S2 and transmits the voltage difference signal S2 to the operation device 223. Then the operation device 223 determines the touch position and touch status according to the voltage difference signal S2.

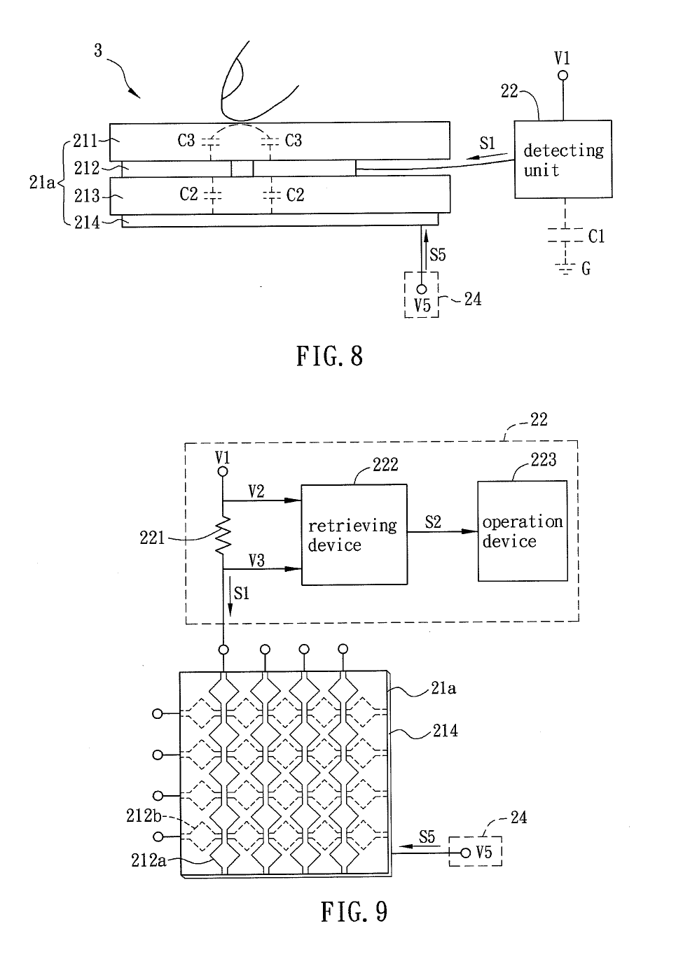

FIG. 8 is a diagram of a touch apparatus of a fifth embodiment of the invention, and FIG. 9 is a circuit diagram of the touch apparatus in FIG. 8. As shown in FIG. 8 and FIG. 9, the touch apparatus 3 includes a touch unit 21a, a detecting unit 22 and a first compensation unit 24. Because the features of the touch unit 21a and the detecting unit 22 are illustrated as the above embodiments, the detailed descriptions thereof are omitted.

The first compensation unit 24 is electrically connected with the electrical shielding layer 214 of the touch unit 21a, and receives a power signal V5 and outputs a first compensation signal S5 to compensate the first and second parasitic capacitances C1 and C2 of the detecting unit 22. Accordingly, the influence of the first and second parasitic capacitances C1 and C2 on the detection of the value and position of a capacitance C3 formed by touching the touch apparatus can be eliminated. In the embodiment, the compensation signal S5 output by the first compensation unit 24 can charge the first and second parasitic capacitances C1 and C2 to the full level. The compensation signal S5 can be synchronized with the driving signal S1, the driving signal S1 and the compensation signal S5 have the same frequency and phase, and the amplitude of the driving signal S1 is less or larger than that of the compensation signal S5. Besides, the first compensation unit 24 can include an energy storing device according to the practical need. In the embodiment, the first compensation unit 24 includes no energy storing device.

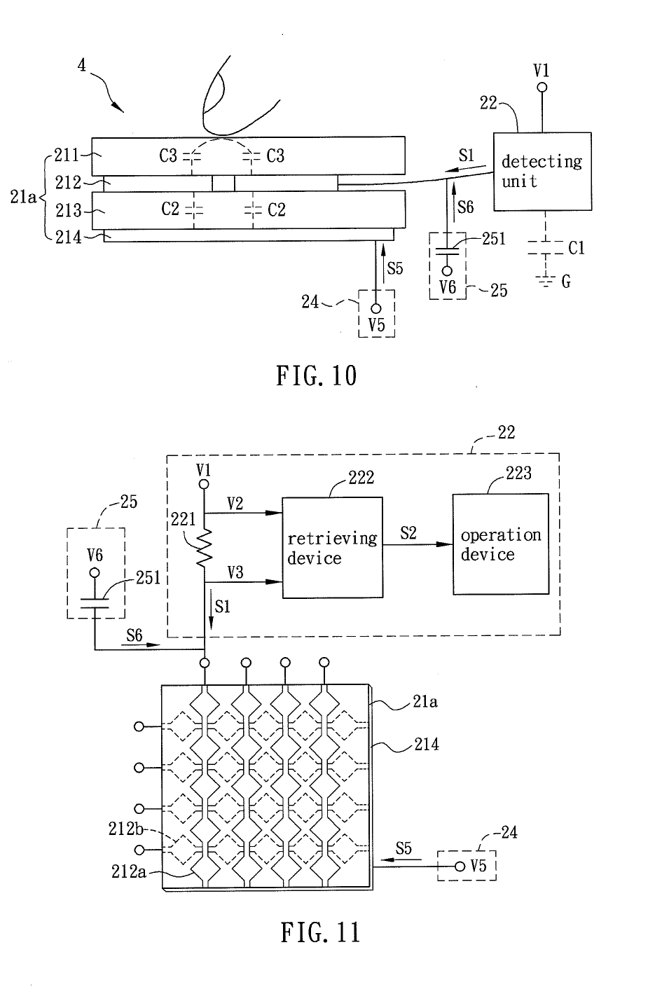

FIG. 10 is a diagram of a touch apparatus of a sixth embodiment of the invention, and FIG. 11 is a circuit diagram of the touch apparatus as shown in FIG. 10. As shown in FIG. 10 and FIG. 11, the touch apparatus 4 of the embodiment further includes a second compensation unit 25.

The second compensation unit 25 is electrically connected with the touch unit 21a and the detecting unit 22, and receives an AC power signal V6 and outputs a second compensation signal S6 to compensate the first parasitic capacitance C1 of the detecting unit 22 and the second parasitic capacitance C2 of the touch unit 21a. The compensation signal S6 can be synchronized with the driving signal S1, the driving signal S1 and the compensation signal S6 have the same frequency and phase, and the amplitude of the driving signal S1 is less or larger than that of the compensation signal S6. Accordingly, the influence of the first and second parasitic capacitances C1 and C2 on the detection of the value and position of the capacitance C3 formed by touching the touch apparatus can be eliminated. In the embodiment, the second compensation signal S6 output by the second compensation 25 can charge the first and second parasitic capacitances C1 and C2 to the full level. Besides, the second compensation unit 25 can include an energy storing device 251 according to the practical need. In the embodiment, the second compensation unit 25 includes an energy storing device 251, and one end of the energy storing device 251 is electrically connected with the conductive layer 212 of the touch unit 21a and the detecting unit 22. The energy storing device of the embodiment is preferably a capacitor.

In summary, the touch apparatus of the invention is configured with a compensation unit, which can output a compensation signal to charge the first and second parasitic capacitances to the full level. Accordingly, when the detecting unit detects the value and position of the capacitance formed by touching the touch apparatus, the detection of the capacitance can not be affected by the first and second parasitic capacitances due to their constant full level. Therefore, the touch apparatus of the invention can eliminate the influence of the parasitic capacitance, so as to enhance the accuracy of the detection of the touch position and touch status.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A touch apparatus, comprising:
a touch unit comprising a touch substrate and at least one conductive layer disposed to a side of the touch substrate;
a detecting unit electrically connected with the conductive layer of the touch unit and outputting a driving signal to the conductive layer, wherein a first parasitic capacitance is formed between the detecting unit and a ground; and
a compensation unit electrically connected with the detecting unit and the conductive layer of the touch unit and outputting a compensation signal to the first parasitic capacitance.

2. The touch apparatus as recited in claim 1, wherein the touch unit further comprises an insulating layer which has a first side and a second side opposite to the first side, wherein the conductive layer is disposed between the first side of the insulating layer and the touch substrate, and the touch unit further comprises a second parasitic capacitance formed between the conductive layer and the second side of the insulating layer.

3. The touch apparatus as recited in claim 2, wherein the compensation signal output by the compensation unit outputs is also transmitted to the second parasitic capacitance.

4. The touch apparatus as recited in claim 2, wherein the touch unit further comprises an electrical shielding layer, the insulating layer is disposed between the conductive layer and the electrical shielding layer, and the material of the electrical shielding layer comprises conductive material.

5. The touch apparatus as recited in claim 1, wherein the conductive layer comprises a column conductive layer and a row conductive layer, both of which are on different planes and not electrically connected with each other.

6. The touch apparatus as recited in claim 1, wherein the detecting unit receives a power signal.

7. The touch apparatus as recited in claim 1, wherein the detecting unit comprises a voltage-drop device, one end of which is electrically connected with the touch unit and the other end of which receives the power signal.

8. The touch apparatus as recited in claim 7, wherein the detecting unit further comprises a retrieving device, the input end of which is electrically with two ends of the voltage-drop device, and the retrieving device receives two voltage signals according to the voltages of the two ends of the voltage-drop device and compares the two voltage signals to output a voltage difference signal.

9. The touch apparatus as recited in claim 8, wherein the detecting unit further comprises an operation device electrically connected with the output end of the retrieving device, and receiving the voltage difference signal to obtain the touch position and touch status according to the variation of the voltage difference signal.

10. The touch apparatus as recited in claim 1, wherein the compensation unit receives a power signal which is an alternating current power signal.

11. The touch apparatus as recited in claim 10, the compensation unit comprises an energy storing device, which is electrically connected with the conductive layer of the detecting unit and separates the power signal from the compensation signal.

12. The touch apparatus as recited in claim 11, wherein the direct current level of the power signal is the same as that of the compensation signal.

13. The touch apparatus as recited in claim 11, where in the energy storing device is a capacitor.

14. The touch apparatus as recited in claim 1, wherein the compensation signal is synchronized with the driving signal, the driving signal and the compensation signal have the same frequency and phase, and the amplitude of the driving signal is less or larger than that of the compensation signal.

15. A touch apparatus, comprising:
a touch unit having a touch substrate, an electrical shielding layer and at least one conductive layer which is disposed between the touch substrate and the electrical shielding layer;
a detecting unit electrically connected with the conductive layer of the touch unit and outputting a driving signal to the conductive layer; and
a first compensation unit electrically connected with the electrical shielding layer,
wherein a first parasitic capacitance is formed between the detecting unit and a ground, a second parasitic capacitance is formed between the conductive layer and the electrical shielding layer, and the compensation unit outputs a first compensation signal to the first parasitic capacitance and the second parasitic capacitance.

16. The touch apparatus as recited in claim 15, wherein the first compensation signal is synchronized with the driving signal, the driving signal and the first compensation signal have the same frequency and phase, and the amplitude of the driving signal is less or larger than that of the first compensation signal.

17. The touch apparatus as recited in claim 15, further comprising:
a second compensation unit electrically connected with the detecting unit and outputting a second compensation signal to the first parasitic capacitance and the second parasitic capacitance.

18. The touch apparatus as recited in claim 17, wherein the second compensation unit receives an alternating current power.

19. The touch apparatus as recited in claim 17, wherein the second compensation unit comprises an energy storing device, which is electrically connected with the conductive layer of the detecting unit and separates the power signal from the second compensation signal.

20. The touch apparatus as recited in claim 17, wherein the second compensation signal is synchronized with the driving signal, the driving signal and the second compensation signal have the same frequency and phase, and the amplitude of the driving signal is less or larger than that of the second compensation signal.
